(19) United States
(12) Patent Application Publication
(10) Pub. No.: US 2023/0163004 A1
(43) Pub. Date: May 25, 2023

(54) PACKAGING DEVICE AND MANUFACTURING METHOD THEREOF

(71) Applicants: Beijing BOE Display Technology Co., Ltd., Beijing (CN); BOE Technology Group Co., Ltd., Beijing (CN)

(72) Inventors: Liangliang ZHAO, Beijing (CN); Junli ZHOU, Beijing (CN); Qiang LI, Beijing (CN); Kaipeng FU, Beijing (CN); Pingli LI, Beijing (CN); Yang LIU, Beijing (CN); Yunyun WANG, Beijing (CN); Yinlong ZHANG, Beijing (CN); Hongtao YANG, Beijing (CN)

(21) Appl. No.: 17/771,692

(22) PCT Filed: Mar. 15, 2021
(86) PCT No.: PCT/CN2021/080790

§ 371 Date: Apr. 25, 2022

(51) Int. Cl. H01L 21/673; B65D 8/00; B65D 43/02; B65D 81/05

(52) U.S. Cl. CPC H01L 21/67343; B65D 15/22; B65D 43/0202; B65D 81/053; B65D 2581/056; B65D 2581/055; B29C 44/12

(57) ABSTRACT

A packaging device and a manufacturing method thereof are provided. The packaging device includes: a bottom plate (1); a side plate (2) fixed to a surface of the bottom plate (1), the bottom plate (1) and the side plate (2) forming a containing cavity through joint enclosure; and a supporting piece (3) in the bottom plate (1). The bottom plate (1) completely wraps the supporting piece (3). An extending direction of the supporting piece (3) is roughly parallel to the surface of the bottom plate (1). A material of the supporting piece (3) is different from that of the bottom plate (1), and a strength of the supporting piece (3) is greater than that of the bottom plate (1).

### CROSS REFERENCE TO RELATED APPLICATIONS

The present application is a national phase entry under 35 U.S.C. §371 of International Application No. PCT/CN2021/080790, filed on Mar. 15, 2021.

### FIELD

The present disclosure relates to the technical field of packaging devices, in particular to a packaging device and a manufacturing method thereof

### BACKGROUND

In the process of manufacturing display panels, it is often necessary to transport the display panels from one place to another place. In order to protect the display panels during transportation, the display panels are usually placed in packaging devices of the display panels.

### SUMMARY

Embodiments of the present disclosure provide a packaging device, including:
a bottom plate;
a side plate fixed to a surface of the bottom plate, wherein the bottom plate and the side plate form a containing cavity through joint enclosure; and
a supporting piece in the bottom plate, wherein the bottom plate completely wraps the supporting piece, and an extending direction of the supporting piece is roughly parallel to the surface of the bottom plate.

A material of the supporting piece is different from that of the bottom plate, and a strength of the supporting piece is greater than that of the bottom plate.

Optionally, in the packaging device provided by the embodiments of the present disclosure, a shape of the bottom plate is rectangular, and the extending direction of the supporting piece is roughly parallel to an extending direction of a long side in the bottom plate.

Optionally, in the packaging device provided by the embodiments of the present disclosure, a shape of the supporting piece is strip-shaped, the quantity of the supporting pieces is multiple, and the multiple supporting pieces are sequentially arranged in an extending direction of a short side in the bottom plate.

Optionally, in the packaging device provided by the embodiments of the present disclosure, the shapes of all supporting pieces are the same, and the multiple supporting pieces are sequentially arranged in the extending direction of the short side in the bottom plate at equal intervals.

Optionally, in the packaging device provided by the embodiments of the present disclosure, a thickness of the bottom plate is 80 mm-90 mm, and a thickness of the supporting piece is 25 mm-35 mm.

Optionally, in the packaging device provided by the embodiments of the present disclosure, a distance between a top face of the supporting piece and a top face of the bottom plate is the same as a distance between a bottom face of the supporting piece and a bottom face of the bottom plate.

Optionally, in the packaging device provided by the embodiments of the present disclosure, the distance between the top face of the supporting piece and the top face of the bottom plate is 25 mm-35 mm, and the distance between the bottom face of the supporting piece and the bottom face of the bottom plate is 25 mm-35 mm.

Optionally, in the packaging device provided by the embodiments of the present disclosure, an orthographic projection of the supporting piece on the surface of the bottom plate has a first long side and a first short side, the surface of the bottom plate has a second short side adjacent to the first short side, and a distance between the first short side and the second short side is 100 mm-200 mm; and a width of the first short side is 30 mm-90 mm.

Optionally, the packaging device provided by the embodiments of the present disclosure further includes stop block(s). A plurality of slots are formed in the side plate, the slots communicate with the containing cavity, and the stop block(s) is/are placed in the slots.

Optionally, in the packaging device provided by the embodiments of the present disclosure, a material of the supporting piece is aluminum.

Optionally, the packaging device provided by the embodiments of the present disclosure further includes a box cover arranged on the side plate in a covering mode. Materials of the bottom plate, the side plate and the box cover are expanded materials.

Optionally, in the packaging device provided by the embodiments of the present disclosure, the expanded materials include expandable polystyrene, or expanded polypropene, or an expanded copolymer composed of polyethylene and polystyrene.

Correspondingly, embodiments of the present disclosure further provide a manufacturing method of the packaging device, including:
providing a first mold having a profile support;
placing a supporting piece on the profile support;
enabling a second mold to be in fit with the first mold;
filling the first mold and the second mold which are in fit with a preset material, wherein the preset material wraps the supporting piece;
processing the filled preset material, and demolding the processed preset material; and
drying the demolded preset material to form the packaging device having a bottom plate and a side plate which is fixed to a surface of the bottom plate, wherein the supporting piece is located in the bottom plate.

Optionally, in the manufacturing method provided by the embodiments of the present disclosure, before filling the first mold and the second mold which are in fit with the preset material, the method further includes:
preheating the first mold and the second mold which are in fit.

Optionally, in the manufacturing method provided by the embodiments of the present disclosure, the processing the filled preset material, and demolding the processed preset material, include:
heating the filled preset material, and forming the bottom plate and the side plate fixed to the bottom plate in the first mold and the second mold;
cooling the bottom plate and the side plate; and
demolding the first mold and the second mold, so as to expose the bottom plate and the side plate.

### BRIEF DESCRIPTION OF THE DRAWINGS

FIG. 1 is a schematic structural diagram of a packaging device provided by an embodiment of the present disclosure;

FIG. 2 is a schematic sectional view along an AA' direction in FIG. 1;

FIG. 3 is a schematic sectional view along a BB' direction in FIG. 1;

FIG. 4 is a schematic diagram of a partial structural in FIG. 2;

FIG. 5 is a schematic plan view of a bottom plate and a supporting piece;

FIG. 6 is a schematic structural diagram of another packaging device provided by an embodiment of the present disclosure;

FIG. 7 is a flow chart of a manufacturing method of a packaging device provided by an embodiment of the present disclosure;

FIG. 8A is a schematic structural diagram of a first mold provided by an embodiment of the present disclosure;

FIG. 8B is a schematic structural diagram of a first mold for placing a supporting piece provided by an embodiment of the present disclosure;

FIG. 9 is a flow chart of a manufacturing method of yet another packaging device provided by an embodiment of the present disclosure.

### DETAILED DESCRIPTION OF THE EMBODIMENTS

In order to make the purpose, technical solutions and advantages of the embodiments of the present disclosure clearer, the implementations of the packaging device and the manufacturing method thereof provided by the embodiments of the present disclosure will be described below in details with reference to the accompanying drawings. It should be understood that the preferred embodiments described below are only used to illustrate and explain the present disclosure and are not used to limit the present disclosure. Moreover, without conflict, the embodiments in the present application and the features in the embodiments can be combined with each other.

The thickness, size and shape of each film layer in the accompanying drawings do not reflect the true ratio, and the purpose is only to illustrate the content of the present disclosure schematically.

Ultra-high-definition large-size display screens will become a trend in the future, and transportation of the super-sized display screens will become a problem. For the transportation of super-sized display panels, it is necessary to use super-large packaging devices. At present, the super-large packaging devices in the prior art mostly adopt a manufacturing method of splicing and forming. For example, two packaging boxes are fixed together by section steel and screws. The forming process is complex and time-consuming, the appearance is bulky and unsightly. In addition, the final packaging device is formed by splicing two parts, the size of the seam is difficult to control, and the sealing performance is poor.

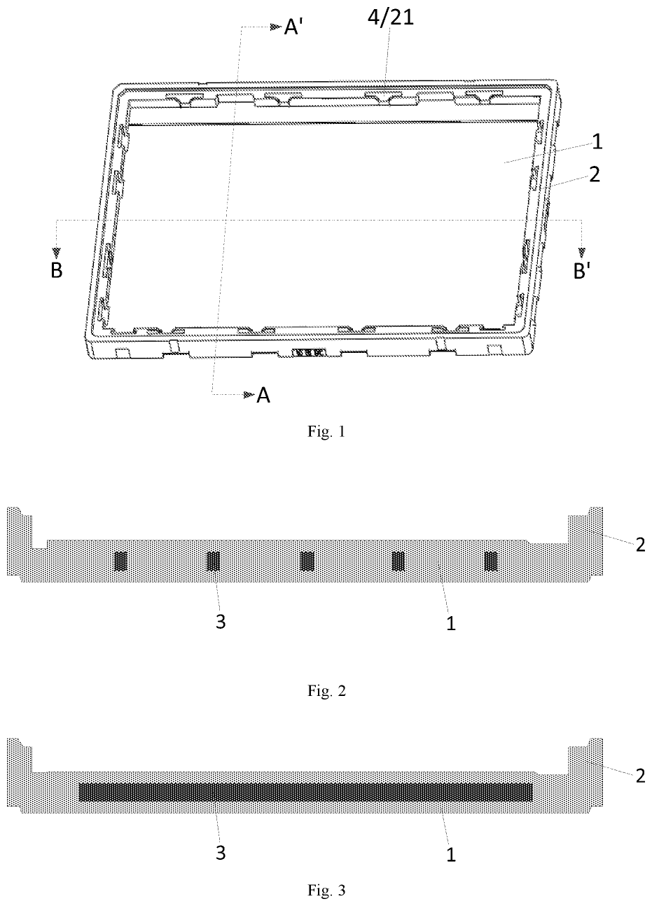

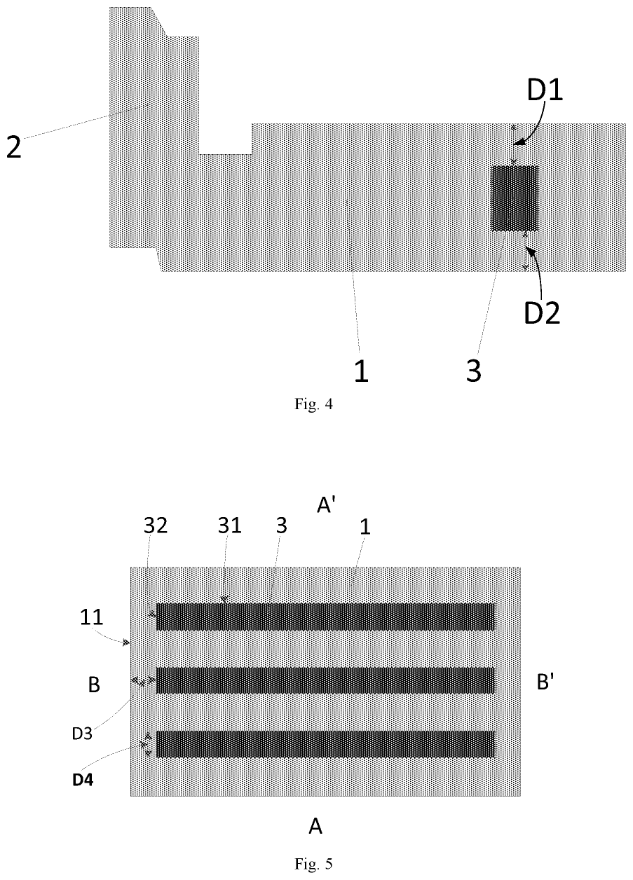

In view of this, embodiments of the present disclosure provide a packaging device, as shown in FIG. 1 and FIG. 2. FIG. 1 is a stereoscopic schematic structural diagram of a packaging device, FIG. 2 is a schematic sectional view along an AA′ direction in FIG. 1. FIG. 3 is a schematic sectional view along a BB′ direction in FIG. 1. FIG. 2 and FIG. 3 only illustrate schematic sectional views of a bottom plate 1, a side plate 2 and a supporting piece 3. The packaging device may include:
a bottom plate 1;
a side plate 2, fixed to a surface of the bottom plate 1, the bottom plate 1 and the side plate 2 forming a containing cavity through joint enclosure; and
a supporting piece 3, located in the bottom plate 1.

The bottom plate 1 completely wraps the supporting piece 3. An extending direction of the supporting piece 3 is roughly parallel to the surface of the bottom plate 1.

A material of the supporting piece 3 is different from that of the bottom plate 1, and a strength of the supporting piece 3 is greater than that of the bottom plate 1.

In the packaging device provided by the embodiments of the present disclosure, the supporting piece is placed inside the bottom plate, and the bottom plate completely wraps the supporting piece, so that when the packaging device is manufactured by a mold, the supporting piece may be placed in the mold firstly, then a material used for manufacturing the packaging device is filled, and thus the packaging device and the supporting piece may be manufactured at one time. The process flow omits the steps of manually assembling the supporting piece and the packaging device, which greatly saves the manufacturing time and the manufacturing cost. In addition, since the packaging device and the supporting piece are manufactured at one time, there is no seam, and the sealing performance is good. The material used for manufacturing the packaging device completely wraps the supporting piece, so that the supporting piece cannot be seen from the appearance, and the appearance is relatively smooth and beautiful. The supporting piece is generally made of a metal material, the supporting piece of the embodiments of the present disclosure is located in the bottom plate, which may not be corroded.

The packaging device provided by the embodiments of the present disclosure may be used for packaging and transporting various types of display panels, such as a Liquid Crystal Display (LCD) panel and an Organic Light-Emitting Diode (OLED) display panel. Of course, the packaging device provided by the embodiments of the present disclosure may also be used for transporting other products. Taking the LCD panel as an example, the LCD panel is placed in the containing cavity formed by joint enclosure of the bottom plate and the annular side plate, movement of the placed LCD panel is prevented through the containing cavity, so that the LCD panel is limited, and the poor quality phenomena such as panel rupture and crack during transportation are avoided.

It should be noted that, as shown in FIG. 1, the containing cavity formed by joint enclosure of the bottom plate 1 and the side plate 2 is illustrated by taking a rectangular containing cavity as an example. Of course, a shape of the containing cavity may also be other shapes, such as square, circle, triangle, trapezoid, etc., which is designed according to actual needs.

In implementations, in the packaging device provided by the embodiments of the present disclosure, as shown in FIGS. 1-3, a shape of the bottom plate 1 is preferably rectangular, and an extending direction of the supporting piece 3 is preferably roughly parallel to an extending direction (BB′ direction) of a long side in the bottom plate 1, so that the quantity of the supporting piece 3 may be reduced.

In implementations, in the packaging device provided by the embodiments of the present disclosure, as shown in FIGS. 1-3, a shape of the supporting piece 3 is preferably strip-shaped, the quantity of the supporting piece 3 is multiple, the multiple supporting pieces 3 are sequentially arranged in an extending direction (AA′ direction) of a short side in the bottom plate 1, and the multiple supporting pieces 3 can improve a supporting performance of the bottom plate 1.

In implementations, in the packaging device provided by the embodiments of the present disclosure, as shown in FIGS. 1-3, the shapes of the supporting pieces 3 are preferably the same, the multiple supporting pieces 3 are sequentially arranged in the extending direction (AA′ direction) of the short side in the bottom plate 1 at equal intervals, so that the supporting performance of the bottom plate 1 can be uniform.

In implementations, in the packaging device provided by the embodiments of the present disclosure, as shown in FIGS. 1-3, a thickness of the supporting piece 3 may be 25 mm-35 mm, preferably 30 mm. A thickness of the bottom plate 1 may be 80 mm-90 mm, preferably 90 mm. Since the thickness of the supporting piece 3 is generally about 30 mm, if the thickness of the bottom plate 1 is less than 80 mm, there is a risk that the bottom plate 1 may not wrap the supporting piece 3. If the thickness of the bottom plate 1 is greater than 90 mm, a material used for manufacturing the bottom plate 1 is wasted, and the cost is increased.

In implementations, in the packaging device provided by the embodiments of the present disclosure, as shown in FIG. 4, FIG. 4 is a partial schematic diagram of FIG. 2. A distance D1 between a top face of the supporting piece 3 and a top face of the bottom plate 1 is the same as a distance D2 between a bottom face of the supporting piece 3 and a bottom face of the bottom plate 2, so that the situation that the supporting piece 3 is exposed, and the beauty of the packaging device is affected can be avoided.

In implementations, in the packaging device provided by the embodiments of the present disclosure, as shown in FIG. 4, the distance D1 between the top face of the supporting piece 3 and the top face of the bottom plate 1 is preferably 25 mm-35 mm, and the distance D2 between the bottom face of the supporting piece 3 and the bottom face of the bottom plate 1 is preferably 25 mm-35 mm.

In implementations, in the packaging device provided by the embodiments of the present disclosure, as shown in FIG. 5, FIG. 5 is a schematic diagram illustrating an orthographic projection relationship of the supporting piece 3 and the bottom plate 1. An orthographic projection of the supporting piece 3 on the surface of the bottom plate 1 has a first long side 31 and a first short side 32. The surface of the bottom plate 1 has a second short side 11 adjacent to the first short side 32. A distance D3 between the first short side 32 and the second short side 11 is preferably 100 mm-200 mm. A width D4 of the first short side 32 is preferably 30 mm-90 mm.

In implementations, the packaging device provided by the embodiments of the present disclosure, as shown in FIG. 1, further includes a stop block 4. A plurality of slots 21 are formed in the side plate 2. The slots 21 communicate with the containing cavity, and the stop block 4 is placed in the slots. The stop block 4 is used for limiting and fixing the whole display panel, so as to prevent the display panel from moving in the containing cavity. A quantity and position of the stop block 4 may be set according to the actual needs.

In implementations, in the packaging device provided by the embodiments of the present disclosure, as shown in FIG. 1, an outer surface of the side plate 2 and an outer surface of the bottom plate 1 further include some structures such as label slots and clasps, which are the same as those in the prior art and will not be detailed here.

In implementations, in the packaging device provided by the embodiments of the present disclosure, the material of the supporting piece is preferably aluminum. Compared with In the prior art, supporting pieces mostly adopt section steel. Compared with section steel, a weight of the supporting piece made of the aluminum material is less, which is convenient for manual handling.

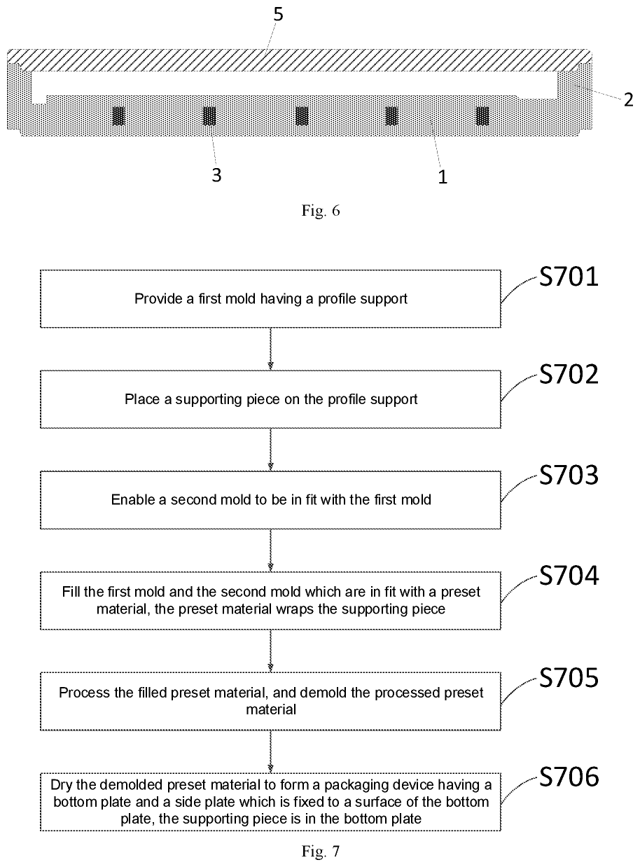

In implementations, the packaging device provided by the embodiments of the present disclosure, as shown in FIG. 6, further includes a box cover 5 arranged on the side plate 2 in a covering mode. Materials of the bottom plate 1, the side plate 2 and the box cover 5 are preferably expanded materials. The expanded materials are soft. When the bottom plate, the side plate and the box cover collide with external objects, a buffering effect can be achieved.

In implementations, in the packaging device provided by the embodiments of the present disclosure, the expanded materials include, but are not limited to, Expandable Polystyrene (EPS), or Expanded Polypropene (EPP), or an Expanded Copolymer (EPO) composed of polyethylene and polystyrene. EPO may be composed by 30% polyethylene and 70% polystyrene.

EPS is made from raw materials through pre-expansion, curing, molding, drying and cutting. It may be made into foam products of different densities and shapes, as well as foam boards of various thicknesses. It is widely used in construction, thermal insulation, packaging, refrigeration, daily necessities, industrial casting and other fields. It may also be used in the manufacture of exhibition venues, merchandise cabinets, advertising signs and toys.

EPP is a high crystalline polymer/gas composite material with an excellent performance. With its unique and superior performance, it has become the fastest-growing novel environmental-protection compression buffer and thermal insulation material.

EPO is a light polymer. It is a foamed plastic with a rigid closed-cell structure formed by adding a foaming agent to polystyrene resin and softening it by heating to generate gas.

The packaging device provided by the embodiments of the present disclosure may package a plurality of display panels. When packaging the plurality of display panels, the quantity of the display panels that may be packaged may be determined according to the internal size of the packaging device at first, then a flexible structure is arranged between every two adjacent display panels, so as to prevent the direct contact between the display panels. In addition, the flexible structures may be arranged on bottom faces and tops of the plurality of display panels, so as to prevent the direct contact between the bottom display panel and the bottom plate and between the top display panel and the box cover, buffering protection is increased, and friction damage is reduced.

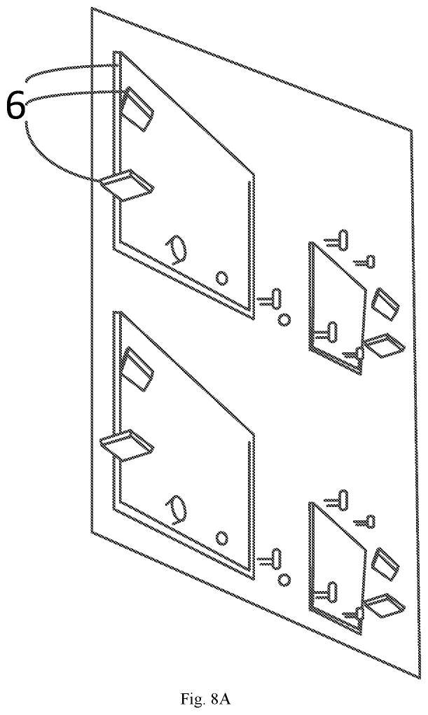

Based on the same inventive concept, embodiments of the present disclosure further provide a manufacturing method of the packaging device, as shown in FIG. 7, the method may include the following steps.

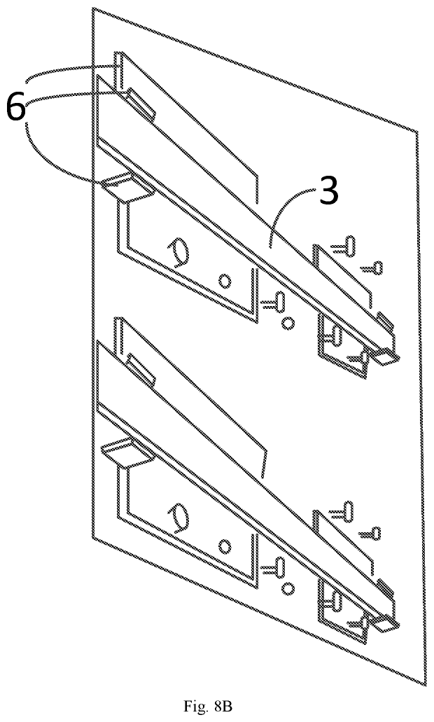

S701, a first mold having a profile support is provided. As shown in FIG. 8A, FIG. 8A is a partial simple schematic structural diagram of the first mold. FIG. 8A only aims to illustrate that the first mold has the profile support 6, and the first mold may be a female mold.

S702, the supporting piece is placed on the profile support. As shown in FIG. 8B, the supporting piece 3 is placed on the profile support 6.

S703, a second mold is enabled to be in fit with the first mold. The second mold may be a male mold, which is not shown in the embodiments of the present disclosure. The second mold is a structure that may be in fit with the first mold to form a to-be-manufactured packaging device.

S704, the first mold and the second mold which are in fit are filled with a preset material. The preset material wraps the supporting piece. The preset material is the above provided expanded material.

S705, the filled preset material is processed, and the processed preset material is demolded.

S706, the demolded preset material is dried to form the packaging device having a bottom plate and a side plate which is fixed to a surface of the bottom plate. The supporting piece is located in the bottom plate.

In the manufacturing method of the packaging device provided by the embodiments of the present disclosure, firstly, the supporting piece is placed on the profile support of the first mold, then the preset material used for manufacturing the packaging device is filled, and then the packaging device with the supporting piece located in the bottom plate is manufactured and obtained through a series of processing processes. That is, the packaging device and the supporting piece may be manufactured at one time. The process flow omits the steps of manually assembling the supporting piece and the packaging device, which greatly saves the manufacturing time and the manufacturing cost. In addition, since the packaging device and the supporting piece are manufactured at one time, there is no seam, and the sealing performance is good. The material used for manufacturing the packaging device completely wraps the supporting piece, so that the supporting piece cannot be seen from the appearance, and the appearance is relatively smooth and beautiful. The supporting piece is generally made of a metal material, and the supporting piece of the embodiments of the present disclosure is located in the bottom plate, which may not be corroded.

In implementations, in the manufacturing method provided by the embodiments of the present disclosure, before the first mold and the second mold which are in fit are filled with the preset material, the method further includes the following step.

The first mold and the second mold which are in fit are preheated. A preheating temperature may be 70° C.-100° C.

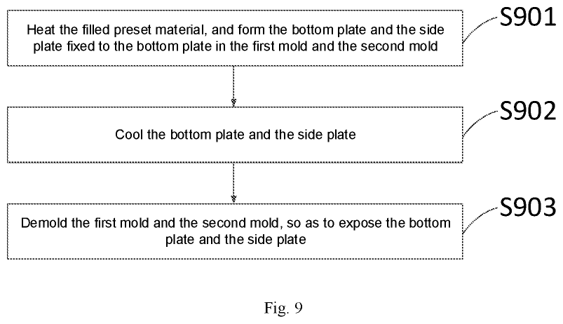

In implementations, in the manufacturing method provided by the embodiments of the present disclosure, the steps that the filled preset material is processed, and the processed preset material is demolded, as shown in FIG. 9, may include the following steps.

S901, the filled preset material is heated, and the bottom plate and the side plate fixed to the bottom plate are formed in the first mold and the second mold. The preset material is the provided expanded material, and the temperature for heating the filled preset material may be 110° C.-130° C., preferably 120° C.

S902, the bottom plate and the side plate are cooled. For example, cold water jet cooling may be adopted.

S903, the first mold and the second mold are demolded, so as to expose the bottom plate and the side plate.

For example, in step S706, the demolded preset material is dried, and the drying temperature may be 55° C.-65° C., preferably 60° C.

In the packaging device and the manufacturing method thereof provided by the embodiments of the present disclosure, the supporting piece is placed in the bottom plate, and the bottom plate completely wraps the supporting piece, so that when the packaging device is manufactured by a mold, the supporting piece may be placed in the mold firstly, then a material used for manufacturing the packaging device is filled, and thus the packaging device and the supporting piece may be manufactured at one time. The process flow omits the steps of manually assembling the supporting piece and the packaging device, which greatly saves the manufacturing time and the manufacturing cost. In addition, since the packaging device and the supporting piece are manufactured at one time, there is no seam, and the sealing performance is good. The material used for manufacturing the packaging device completely wraps the supporting piece, so that the supporting piece cannot be seen from the appearance, and the appearance is relatively smooth and beautiful. The supporting piece is generally made of a metal material, the supporting piece of the embodiment of the present disclosure is located in the bottom plate, which may not be corroded.

Obviously, those skilled in the art can make various changes and modifications to the present disclosure without departing from the spirit and scope of the present disclosure. As such, provided that these modifications and variations of the present disclosure fall within the scope of the claims of the present disclosure and their equivalents, the present disclosure is also intended to cover such modifications and variations.

1. A packaging device, comprising:
a bottom plate;
a side plate, fixed to a surface of the bottom plate, wherein the bottom plate and the side plate form a containing cavity through joint enclosure; and
a supporting piece in the bottom plate, wherein the bottom plate completely wraps the supporting piece, and an extending direction of the supporting piece is roughly parallel to the surface of the bottom plate;
wherein a material of the supporting piece is different from a material of the bottom plate, and a strength of the supporting piece is greater than a strength of the bottom plate.

2. The packaging device according to claim 1, wherein:
a shape of the bottom plate is rectangular; and
the extending direction of the supporting piece is roughly parallel to an extending direction of a long side in the bottom plate.

3. The packaging device according to claim 2, wherein:
a shape of the supporting piece is strip-shaped;
the quantity of the supporting piece is multiple; and
the multiple supporting pieces are sequentially arranged in an extending direction of a short side in the bottom plate.

4. The packaging device according to claim 3, wherein:
the shapes of the multiple supporting pieces are same; and
the multiple supporting pieces are sequentially arranged in the extending direction of the short side in the bottom plate at equal intervals.

5. The packaging device according to claim 1, wherein:
a thickness of the bottom plate is 80 mm-90 mm; and
a thickness of the supporting piece is 25 mm-35 mm.

6. The packaging device according to claim 1, wherein:
a distance between a top face of the supporting piece and a top face of the bottom plate is same as a distance between a bottom face of the supporting piece and a bottom face of the bottom plate.

7. The packaging device according to claim 6, wherein:
the distance between the top face of the supporting piece and the top face of the bottom plate is 25 mm-35 mm; and
the distance between the bottom face of the supporting piece and the bottom face of the bottom plate is 25 mm-35 mm.

8. The packaging device according to claim 2, wherein:
an orthographic projection of the supporting piece on the surface of the bottom plate has a first long side and a first short side;
the surface of the bottom plate has a second short side adjacent to the first short side;
a distance between the first short side and the second short side is 100 mm-200 mm; and
a width of the first short side is 30 mm-90 mm.

9. The packaging device according to claim 1, further comprising:
a stop block;
wherein a plurality of slots are formed in the side plate, the slots communicate with the containing cavity, and the stop block is placed in the slots.

10. The packaging device according to claim 1, wherein the material of the supporting piece is aluminum.

11. The packaging device according to claim 1, further comprising:
a box cover arranged on the side plate in a covering mode;
wherein materials of the bottom plate, the side plate and the box cover are expanded materials.

12. The packaging device according to claim 11, wherein the expanded materials comprise:
expandable polystyrene, or
expanded polypropene, or
an expanded copolymer composed of polyethylene and polystyrene.

13. A manufacturing method of the packaging device according to claim 1, comprising:
providing a first mold having a profile support;
placing the supporting piece on the profile support;
enabling a second mold to be in fit with the first mold;
filling the first mold and the second mold which are in fit with a preset material, wherein the preset material wraps the supporting piece;
processing the filled preset material, and demolding the processed preset material; and
drying the demolded preset material to form the packaging device having the bottom plate and the side plate which is fixed to the surface of the bottom plate, wherein the supporting piece is in the bottom plate.

14. The manufacturing method according to claim 13, wherein before filling the first mold and the second mold which are in fit with the preset material, the method further comprises:
preheating the first mold and the second mold which are in fit.

15. The manufacturing method according to claim 13, wherein the processing the filled preset material, and demolding the processed preset material, comprise:
heating the filled preset material, and forming the bottom plate and the side plate fixed to the bottom plate in the first mold and the second mold;
cooling the bottom plate and the side plate; and
demolding the first mold and the second mold, so as to expose the bottom plate and the side plate.
